(19) United States
(12) Patent Application Publication
(10) Pub. No.: US 2019/0028361 A1
(43) Pub. Date: Jan. 24, 2019

(54) SYSTEM AND METHOD FOR MONITORING MULTIPLE DEVICES IN MULTIPLE NETWORKS

(71) Applicant: HONGFUJIN PRECISION ELECTRONICS (TIANJIN) CO.,LTD., Tianjin (CN)

(72) Inventors: SHENG-CHUNG PAN, New Taipei (TW); YEN-HSUAN CHEN, New Taipei (TW); YIN-YEN CHIEN, New Taipei (TW); TING-CHIEH LIN, New Taipei (TW)

(21) Appl. No.: 15/792,626

(22) Filed: Oct. 24, 2017

(30) Foreign Application Priority Data
Jul. 21, 2017 (CN) 201710601586.0

(51) Int. Cl. H04L 12/24; G01R 21/133; G06F 1/28; G06F 1/26; G06F 3/14

(52) U.S. Cl. CPC H04L 41/22; H04L 41/26; G01R 21/133; H04L 41/04; G06F 1/266; G06F 3/1462; G06F 1/28

(57) ABSTRACT

A system which can be applied in a common server for monitoring multiple devices in a network includes setting a logging program into each of the devices whereby each device updates and outputs a log file to the server at preset times. The coupling of a new IP address (of a new device) to the network can be detected and added. The system monitors all the devices for normal or cautionary or abnormal running and posts notifications to a manager if abnormal running occurs. A device monitoring method is further provided.

### FIELD

The subject matter herein generally relates to a network monitoring system and method for monitoring a plurality of devices.

### BACKGROUND

A server manager can monitor and service a plurality of devices located at different network sites. The server manager can be coupled to the plurality of devices through Internet Control Messages Protocol (ICMP) or Simple Network Server monitoring Protocol (SNMP).

### BRIEF DESCRIPTION OF THE DRAWINGS

Implementations of the present technology will now be described, by way of example only, with reference to the attached figures.

FIG. 1 is a diagram of an exemplary embodiment of a device monitoring system.

FIG. 2 is a block diagram of the device monitoring system of FIG. 1.

FIG. 3 is a flow diagram of an exemplary embodiment of a device monitoring method.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

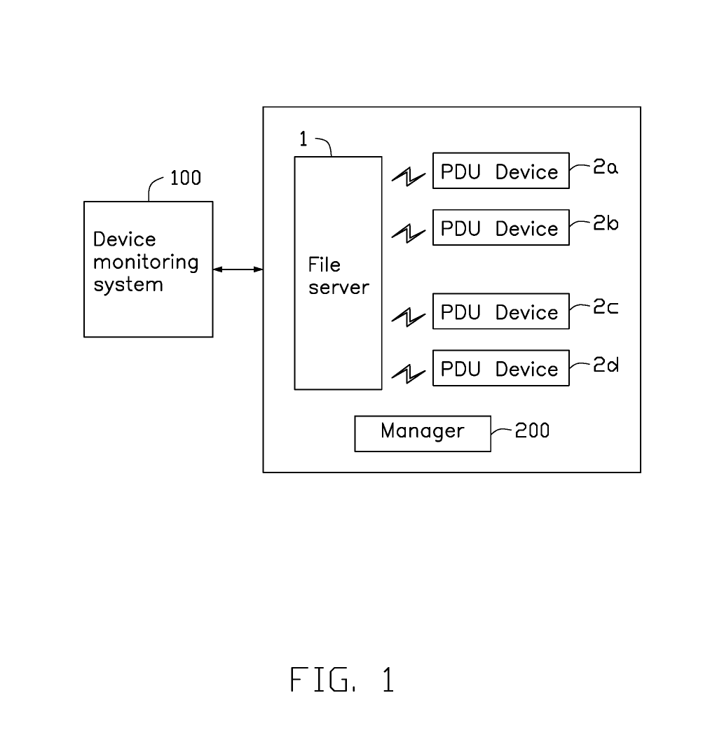

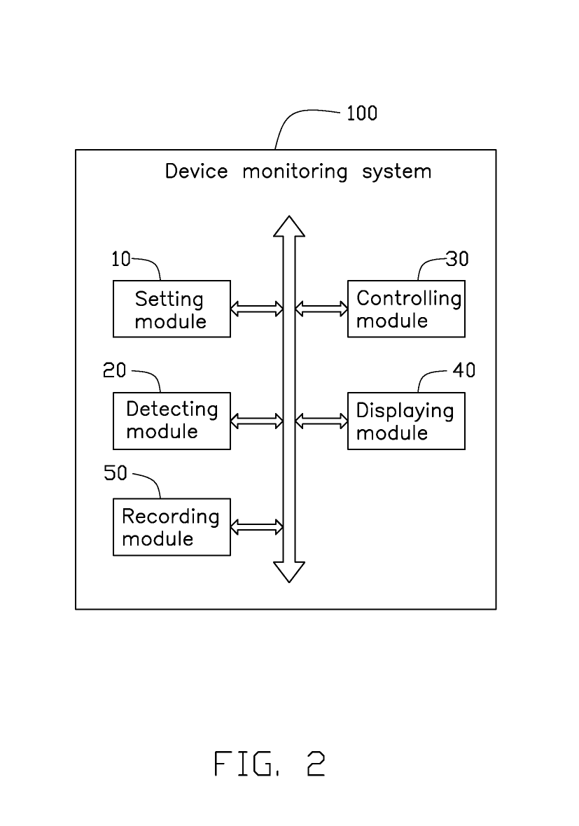

FIG. 1 and FIG. 2 illustrate a device monitoring system 100 in accordance with a first exemplary embodiment.

The device monitoring system 100 is configured to monitor the running status of each of a plurality of power distribution unit (PDU) devices. Each of the plurality of PDU devices is coupled to a file server. The plurality of PDU devices and the file server constitute a monitored network, and the device monitoring system 100 is authorized to monitor the running status of each of a plurality of PDU devices in the monitored network. In this exemplary embodiment, the plurality of PDU devices includes PDU devices 2a, 2b, 2c, and 2d.

The device monitoring system 100 can be installed in a file server or a personal computer. The device monitoring system 100 of this exemplary embodiment is installed in a file server 1.

The device monitoring system 100 obtains the running status of each of the PDU devices 2a, 2b, 2c, and 2d from the file server 1. The device monitoring system 100 can include a setting module 10, a detecting module 20, a controlling module 30, a displaying module 40, and a recording module 50.

In at least one exemplary embodiment, the setting module 10 installs a log tool into each of PDU devices 2a, 2b, 2c, and 2d, so that each PDU device can update and output a log file to the file server 1 at preset time intervals. The log tool can be a program file added in a log file feedback system. The log tool can define the preset time intervals for updating the log file and outputting the updated log file. In at least one exemplary embodiment, the preset time interval is 30 seconds, so that each of the PDU devices 2a, 2b, 2c, and 2d updates the log file and outputs the updated log file to the file server 1 every 30 seconds.

Each of the PDU devices 2a, 2b, 2c, and 2d has a unique IP address. The detecting module 20 is configured to detect a new IP address accessing or attempting to access the monitored network. When a new IP address from an unregistered device (e.g., a PDU device) attempts to connect to or register with the file server 1, the unregistered device is deemed to be accessing the monitored network, and the detecting module 20 adds the new IP address into the monitored network. Once the new IP address of the now newly registered device is connected to the file server 1, the newly registered device is allowed access into the monitored network. The setting module 10 then installs the log tool into the newly registered device so that the newly registered device can update and output a log file to the file server 1 at preset time intervals. The log tool can be a program file added in a log file feedback system. The log tool can define the preset time intervals for the newly registered device to update its log file and outputting the updated log file. As such, the newly registered device can be monitored by the device monitoring system 100.

In at least one exemplary embodiment, the log file can record manager information, software information, version information, and running information of each of the PDU devices 2a, 2b, 2c, and 2d. A manager 200 manages and maintains each of the PDU devices or all of them. The running information can include voltage, current, power, temperature, and IP address.

The controlling module 30 receives the log file from the file server 1 and controls the displaying module 40 to display the recorded information in the log file of each of the PDU devices 2a, 2b, 2c, and 2d. The recorded information of each of the PDU devices 2a, 2b, 2c, and 2d can be viewed by entering the corresponding IP address in the displaying module 40.

In at least one exemplary embodiment, the controlling module 30 can further determine whether the monitored network is in an abnormal state based upon the information in the log file. Information regarding abnormalities is displayed by the displaying module 40, and a notification is sent to the manager 200. If at least one of the plurality of devices is in an abnormal state, the monitored network is deemed to be in an abnormal state.

The controlling module 30 further sets warning levels corresponding to each of the PDU devices 2a, 2b, 2c, 2d according to the log, and controls the displaying module 40 to label the warning levels of each PDU device 2a, 2b, 2c, 2d.

The warning levels can include normal, caution, and abnormal levels, and the controlling module 30 determines the warning level applicable to each of the PDU devices 2a, 2b, 2c, and 2d.

The controlling module 30 sets a first preset value and a second preset value, and the controlling module 30 further compares the current consumption of each of the PDU devices 2a, 2b, 2c, and 2d with the first preset value and the second preset value.

For example, when the current consumption of the PDU device 2a is less than the first preset value, the controlling module 30 determines that the warning level of the PDU device 2a is the normal level, and the controlling module 30 controls the displaying module 40 to mark the running information of the PDU device 2a in green, to indicate that the PDU device 2a is in a normal state.

When the current of the PDU device 2a is greater than the first preset value and less than the second preset value, the controlling module 30 determines that the warning level of the PDU device 2a is the caution level, and the module 30 controls the displaying module 40 to mark the running information of the PDU device 2a in yellow, to indicate that the PDU device 2a is in a warning state.

When the current of the PDU device 2a is greater than the second preset value, the controlling module 30 determines that the warning level of the PDU device 2a is the abnormal level, and the module 30 controls the displaying module 40 to mark the running information of the PDU device 2a in red, to indicate that the PDU device 2a is in an abnormal state.

When the controlling module 30 determines that the warning level of a PDU device is at the abnormal level, a notification is sent to the manager 200.

In this exemplary embodiment, each PDU device sends the log file to the device monitoring system 100 every 30 seconds, thus the device monitoring system 100 can get a log file before the abnormal PDU device goes offline, so that the manager can perform an offline analysis according to the last log file.

The warning level detection principles and determinations of the PDU devices 2b, 2c, and 2d are the same as for the PDU device 2a, and will not be described again.

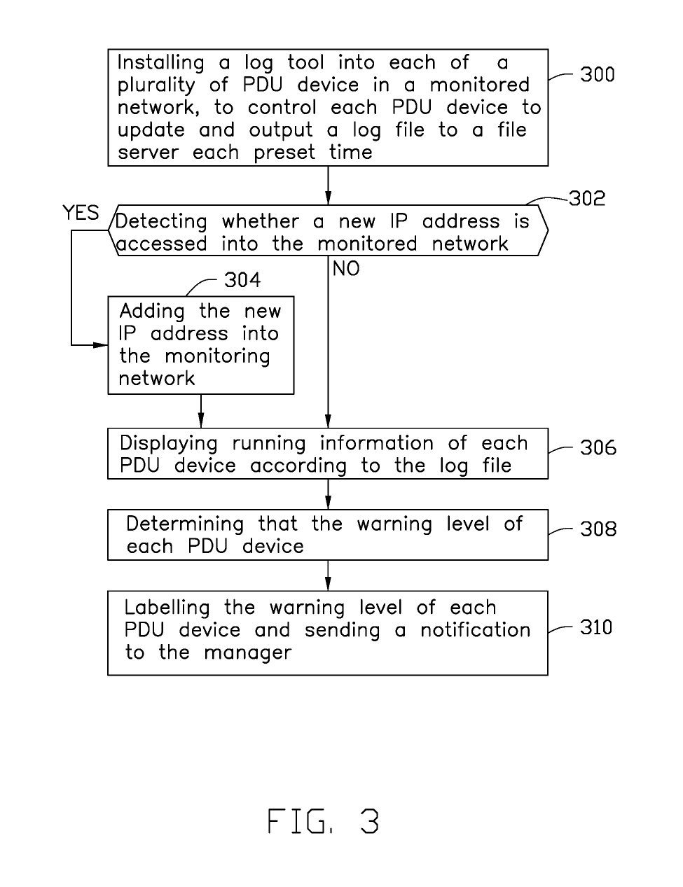

FIG. 3 is a flowchart depicting an exemplary embodiment of a device monitoring method. The method is provided by way of example, as there are a variety of ways to carry out the method. The exemplary method described below can be carried out using the configurations illustrated in FIGS. 1-2, for example, and various elements of these figures are referenced in explaining the example method. Each block shown in FIG. 3 represents one or more processes, methods, or subroutines, carried out in the example method. Furthermore, the illustrated order of blocks is illustrative only and the order of the blocks can change. Additional blocks can be added or fewer blocks may be utilized, without departing from the present disclosure. The example method can begin at block 300.

At block 300, the setting module 10 sets a log tool into each PDU device, and each PDU device updates and outputs a log file to the file server 1 at each preset time.

At block 302, the detecting module 20 detects whether a new IP address is allowed access into the monitored network (e.g., whether a new IP address from an unregistered device attempts to connect to or register with the file server 1 in FIG. 1). If the outcome of block 302 is yes, block 304 is performed. Otherwise, block 306 is performed.

At block 304, the detecting module 20 adds the new IP address into the monitored network, then proceeds to block 306. Once the new IP address of the now newly registered device is connected to the file server 1, the newly registered device is allowed access into the monitored network. The setting module 10 then installs the log tool into the newly registered device so that the newly registered device can update and output its log file to the file server 1 at preset time intervals. The log tool can be a program file added in a log file feedback system. The log tool can define the preset time intervals for the newly registered device to update its log file and outputting the updated log file. As such, the newly registered device can be monitored by the device monitoring system 100.

At block 306, the controlling module 30 controls the displaying module 40 to display the running information of each PDU device according to the log file.

In at least an exemplary embodiment, the running information can include voltage, current, power, temperature and IP address.

At block 308, the controlling module 30 determines that the warning level of each PDU device.

In at least an exemplary embodiment, the warning levels can be normal, caution, and abnormal levels and the controlling module 30 determines the warning level applicable to each of the PDU devices 2a, 2b, 2c, and 2d. The controlling module 30 sets a first preset value and a second preset value, and the controlling module 30 further compares the current consumption of each PDU device 2a, 2b, 2c, and 2d with the first preset value and the second preset value.

At block 310, the controlling module 30 controls the displaying module 40 to label the warning level of each the PDU devices 2a, 2b, 2c, 2d, and a notification is sent to the manager 200.

For example, when the current consumption of the PDU device 2a is less than the first preset value, the controlling module 30 determines that the warning level of the PDU device 2a is the normal level, and the controlling module 30 controls the displaying module 40 to mark the running information of the PDU device 2a in green, to indicate that the PDU device 2a is in a normal state.

When the current consumption of the PDU device 2a is greater than the first preset value and less than the second preset value, the controlling module 30 determines that the warning level of the PDU device 2a is the caution level, and the module 30 controls the displaying module 40 to mark the running information of the PDU device 2a in yellow, to indicate that the PDU device 2a is a warning state.

When the current consumption of the PDU device 2a is greater than the second preset value the controlling module 30 determines that the warning level of the PDU device 2a is the abnormal level, and the module 30 controls the displaying module 40 to mark the running information of the PDU device 2a in red, to indicate that the PDU device 2a is an abnormal state.

When the controlling module 30 determines that the PDU device 2a is in the abnormal level, and a notification is sent to the manager 200.

The exemplary embodiments shown and described above are only examples. Many details are often found in the art such as the other features of device monitoring system and method. Therefore, many such details are neither shown nor described.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A device monitoring method comprising:
installing a log tool into a first device in a monitored network, the log tool controlling the first device to update and output a first log file to a file server;
adding an IP address of a second device into the monitored network when the IP address from the second device is connected to the file server, the second device updating and outputting a second log file to the file server;
setting a warning level to the first device according to the log file; and
monitoring whether each of the first and second devices is in an abnormal level according to the corresponding one of the first and second log files, and recording abnormal information to send as a notification information to a manager;
wherein the monitored network comprises the file server and the first and second devices connected to the file server; and each of the first and second devices has a unique IP address.

2. The device monitoring method of claim 1, wherein each of the first and second log files records manager information and running information of each of the corresponding first and second devices.

3. The device monitoring method of claim 2, wherein further comprising:
setting a first preset value and a second preset value; and
comparing the current consumption of each of the first and second devices with the first preset value and the second preset value.

4. The device monitoring method of claim 3, wherein further comprising:
determining that the warning level of at least one of the first and second devices is in a normal level when the current consumption of the at least one of the first and second devices is less than the first preset value;
determining that the warning level of the at least one of the first and second devices is in a caution level when the current consumption of the at least one of the first and second devices is greater than the first preset value and less than the second preset value; and
determining that the warning level of the at least one of the first and second devices is in the abnormal level when the current consumption of the at least one of the first and second devices is greater than the second preset value.

5. The device monitoring method of claim 2, wherein further comprising:
labeling the warning level of at least one of the first and second devices;
marking the warning level in green when the at least one of the first and second devices is in the normal level;
marking the warning level in yellow when the at least one of the first and second devices is in the caution level; and
marking the warning level in red when the at least one of the first and second devices is in the abnormal level.

6. The device monitoring method of claim 1, wherein when the IP address of the second device is connected to the file server, the second device is allowed access into the monitored network, and the log tool controls the second device to update and output the second log file to the file server.

7. The device monitoring method of claim 1, wherein the preset time is 30 seconds.

8. The device monitoring method of claim 1, further comprising receiving the first and second log files from the first and second devices, respectively, and control a displaying module to display the recorded information in the first and second log files.

9. The device monitoring method of claim 1, wherein the log tool is a program file added in a log file feedback system to define the preset time for updating the first and second log files and outputting the updated first and second log files.

10. A device monitoring system, comprising:
a setting module installing a log tool into a first device in a monitored network, to control the first device to update and output a first log file to a file server at preset time intervals;
a detecting module detecting whether an IP address of a second device is connected to the file server and add the IP address into the monitored network when the IP address of the second device is connected to the file server, the second device updating and outputting a second log file to the file server; and
a controlling module controlling a displaying module to display a running information of each of the first and second devices according to the corresponding one of the first and second log files; and
the controlling module setting a warning level corresponding to each of the first and second devices according to the corresponding one of the first and second log files, and monitoring whether each of the first and second devices is in an abnormal level according to the corresponding one of the first and second log files, and recording abnormal information to send as a notification information to a manager;
wherein the monitored network comprises the file server and the first and second devices connected to the file server; and each of the first and second devices has a unique IP address.

11. The device monitoring system of claim 11, wherein each of the first and second log files records manager information and running information of each of the corresponding first and second devices.

12. The device monitoring system of claim 11, wherein the controlling module sets a first preset value and a second preset value, and compares the current consumption of each of the first and second devices with the first preset value and the second preset value.

13. The device monitoring system of claim 12, wherein when the current consumption of at least one of the first and second devices is less than the first preset value, the controlling module determines that the warning level of the at least one of the first and second devices is in a normal level; when the current consumption of the at least one of the first and second devices is greater than the first preset value and less than the second preset value, the controlling module determines that the warning level of the of the at least one of the first and second devices is in a caution level; when the current consumption of the at least one of the first and second devices is greater than the second preset value, the controlling module determines that the warning level of the of the at least one of the first and second devices is in the abnormal level.

14. The device monitoring system of claim 13, wherein the controlling module controls the displaying module to label the warning level of the at least one of the first and second devices.

15. The device monitoring system of claim 10, wherein when the IP address of the second device is connected to the file server, the second device is allowed access into the monitored network, and the log tool controls the second device to update and output the second log file to the file server.

16. The device monitoring system of claim 10, wherein the preset time is 30 seconds.

17. The device monitoring system of claim 10, wherein the log tool is a program file added in a log file feedback system to define the preset time for updating each of the first and second log files and outputting the updated first and second log files.
